(19) United States
(12) Patent Application Publication
(10) Pub. No.: US 2025/0093769 A1
(43) Pub. Date: Mar. 20, 2025

(54) MASK QUALITY MANAGEMENT SYSTEM

(71) Applicant: Samsung Display Co., LTD., Yongin-si (KR)

(72) Inventors: SUNGMIN HUR, Yongin-si (KR); HYENG-WOO CHO, Yongin-si (KR)

(21) Appl. No.: 18/749,793

(22) Filed: Jun. 21, 2024

(30) Foreign Application Priority Data
Sep. 20, 2023 (KR) 10-2023-0125935

(51) Int. Cl. G03F 1/84; G03F 7/00

(52) U.S. Cl. CPC G03F 1/84; G03F 7/70425; G03F 7/706849

(57) ABSTRACT

A mask quality management system includes a mask including a mask frame and a plurality of mask sheets, wherein the mask sheets are fixed to an upper surface of the mask frame and disposed to be spaced apart from each other, a stage on which the mask is seated, and a first module disposed on the stage and measuring a sagging degree of the mask sheet from the mask frame by irradiating an intense light to the mask.

This application claims priority to Korean Patent Application No. 10-2023-0125935, filed on Sep. 20, 2023, and all the benefits accruing therefrom under 35 U.S.C. § 119, the content of which in its entirety is herein incorporated by reference.

### BACKGROUND

### 1. Field

The disclosure relates to a mask quality management system, and more particularly to a mask quality management system used in a manufacturing process of a display device.

### 2. Description of the Related Art

A mask may be used in a manufacturing process of a display device. A plurality of openings is defined in the mask. The plurality of openings defined in the mask has a certain size, a certain shape, and a certain arrangement.

### SUMMARY

When the size, shape, arrangement, etc., of the plurality of openings defined in the mask are different from a design, a quality of the display device may deteriorate. For example, undeposited shadow areas may occur in the display device.

The disclosure relates to a mask quality management system with an improved measurement speed and measurement accuracy.

The disclosure relates to a mask quality management system capable of removing foreign substances from a surface of a mask sheet.

An embodiment of a mask quality management system includes a mask including a mask frame and a plurality of mask sheets fixed to an upper surface of the mask frame and spaced apart from each other, a stage on which a mask of the plurality of mask sheets is seated, and a first module disposed on the stage and measuring a sagging degree of the mask sheet from the mask frame by irradiating an intense light to the mask.

In an embodiment, the first module may include a beam generator that emits light, a lens through which the light emitted from the beam generator passes and by which the light enters the mask and includes a focus, a beam splitter through which the light passing through the lens is incident, a detection sensor that converts the light reflected from the beam splitter into an electrical signal, and a camera that generates image information based on the light passing through the beam splitter.

In an embodiment, the first module may measure the sagging degree of the mask sheet by scan throughout the mask.

In an embodiment, in a case that the sagging degree of the mask sheet satisfies a predetermined numerical range, the mask may be determined to be a normal mask, and in a case that the sagging degree of the mask sheet is outside the predetermined numerical range, the mask may be determined to be a defective mask.

In an embodiment, the first module may measure the sagging degree of the mask sheet from the mask frame at a micrometer level.

In an embodiment, the mask quality management system may further include a second module which is disposed on the stage, provides a gas to the mask.

In an embodiment, the second module may include a blower that provides the gas to the mask and a suction which suctions foreign substances dropped by the gas from the surface of the mask.

In an embodiment, a down flow may be included (formed) in the stage.

In an embodiment, a plurality of vents through which the gas is discharged may be defined in a blowing surface of the blower.

In an embodiment, the gas may include either nitrogen gas or clean dry air.

Another embodiment of a mask quality management system may include a mask including a mask frame and a plurality of mask sheets fixed to an upper surface of the mask frame and spaced apart from each other, a stage on which a mask of the plurality of mask sheets is seated, and a second module which is disposed on the stage, provides a gas to the mask.

In an embodiment, the second module may include a blower that provides the gas to the mask and a suction which suctions foreign substances dropped by the gas from the surface of the mask.

In an embodiment, a down flow may be included (formed) in the stage.

In an embodiment, a plurality of vents through which the gas is discharged may be defined in a blowing surface of the blower.

In an embodiment, the gas may include either nitrogen gas or clean dry air.

In an embodiment, the mask quality management system may further include a first module which is disposed on the stage and measures the sagging degree of the mask sheet in a direction crossing an extension direction of the mask by irradiate an intense light to the mask.

In an embodiment, the first module may include a beam generator that emits light, a lens through which the light emitted from the beam generator passes and by which the light enters the mask and includes a focus, a beam splitter through which the light passing through the lens is incident, a detection sensor that converts the light reflected from the beam splitter into an electrical signal, and a camera that generates image information based on the light passing through the beam splitter.

In an embodiment, the first module may measure the sagging degree of the mask sheet by scan throughout the mask.

In an embodiment, in a case that the sagging degree of the mask sheet satisfies a predetermined numerical range, the mask may be determined to be a normal mask, and in a case that the sagging degree of the mask sheet is outside the predetermined numerical range, the mask may be determined to be a defective mask.

In an embodiment, the first module may measure the sagging degree of the mask sheet from the mask frame at a micrometer level.

As described above, in embodiments, since the mask quality management system includes a mask including a mask frame and a plurality of mask sheets, where the mask sheets are fixed to an upper surface of the mask frame and disposed to be spaced apart from each other, a stage on which the mask is seated, and a first module disposed on the stage and measuring a sagging degree of the mask sheet from the mask frame by irradiating an intense light to the mask. By identifying the defective mask in advance and not using the defective mask in a deposition process, a shadow defect may be prevented.

In addition, the mask quality management system may further include a second module disposed on the stage and providing the gas to the mask to remove the foreign substances from the surface of the mask. As the foreign substance is removed, yield of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a view illustrating an embodiment of a mask quality management system, according to the disclosure.

FIG. 2 is a view illustrating the first module included in the mask quality management system of FIG. 1.

FIGS. 3 and 4 are views illustrating a mask that is subject to inspection by the mask quality management system of FIG. 1.

FIG. 5 is view illustrating an inspection result by the first module of FIG. 2.

FIG. 6 is a view illustrating a second module included in the mask quality management system of FIG. 1.

FIG. 7 is a view illustrating a vent of a blower included in the second module of FIG. 6.

FIGS. 8, 9, and 10 are vews illustrating a result of removing the foreign substances by the second module of FIG. 6.

### DETAILED DESCRIPTION

Embodiments of the disclosure now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

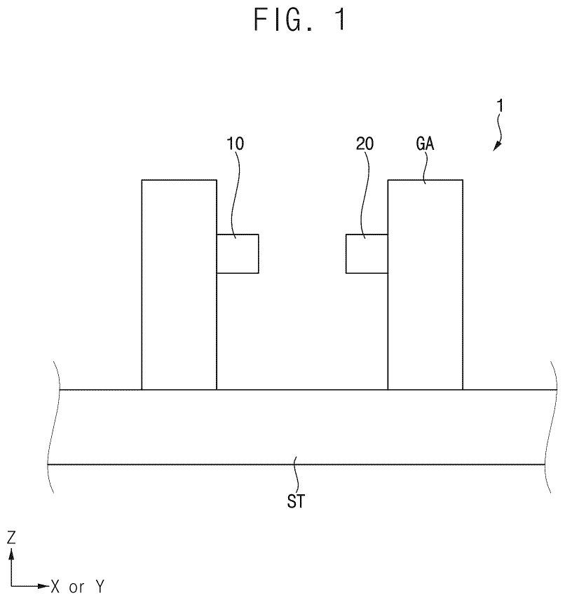

FIG. 1 is a view illustrating an embodiment of a mask quality management system, according to the disclosure.

Referring to FIG. 1, a mask quality management system 1 in embodiments of the disclosure may include a stage ST, a gantry GA, a first module 10, and a second module 20.

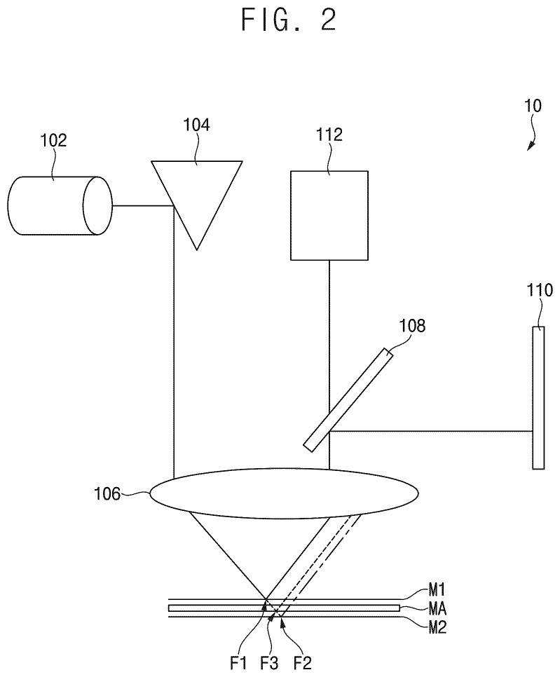

In an embodiment, a mask (e.g., a mask MA of FIG. 2) may be placed on the stage ST. In an embodiment, the stage ST may move in a plan view defined by a first direction and a second direction crossing the first direction, or may move in a third direction crossing the plane, for example. In an embodiment, the first direction may be a X direction, the second direction may be a Y direction, and the third direction may be a Z direction, for example. However, the disclosure is not limited thereto. The stage ST may be fixed, the first direction may be the Y direction, and the second direction may be the X direction.

The first module 10 and the second module 20 may be placed on the gantry GA. In an embodiment, the gantry GA may move in the plan view defined by the first direction and the second direction, or may move in the third direction, for example.

As the gantry GA or the stage ST moves in the plan view defined by the first direction and the second direction, the entirety of the mask MA may be scanned, and as the gantry GA or the stage ST moves in the third direction, a distance between the mask MA and the first module 10 and/or a distance between the mask MA and the second module 20 may be adjusted.

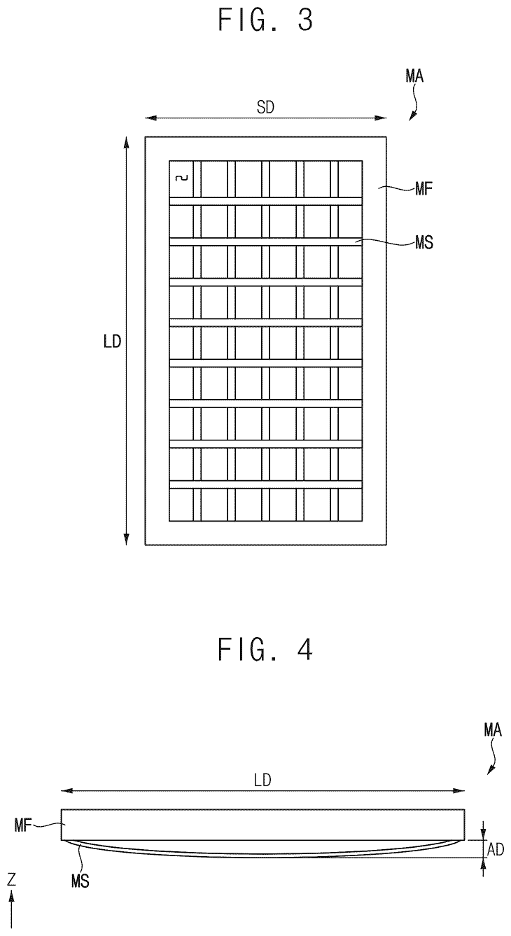

As described above, the first module 10 may be placed on the gantry GA. The first module 10 may inspect a defect of the mask MA disposed (e.g., mounted) on the stage ST. In an embodiment, the first module 10 may be disposed on the stage ST, and the first module 10 may measure a sagging degree of a mask sheet (e.g., a mask sheet MS of FIG. 3) from a mask frame MF by irradiating an intense light (e.g., laser beam) to the mask MA. When the sagging degree of the mask sheet is outside a predetermined numerical range, the mask MA may be determined to be a defective mask. A detailed description of the first module 10 will be described later with reference to FIGS. 2, 3, 4, and 5.

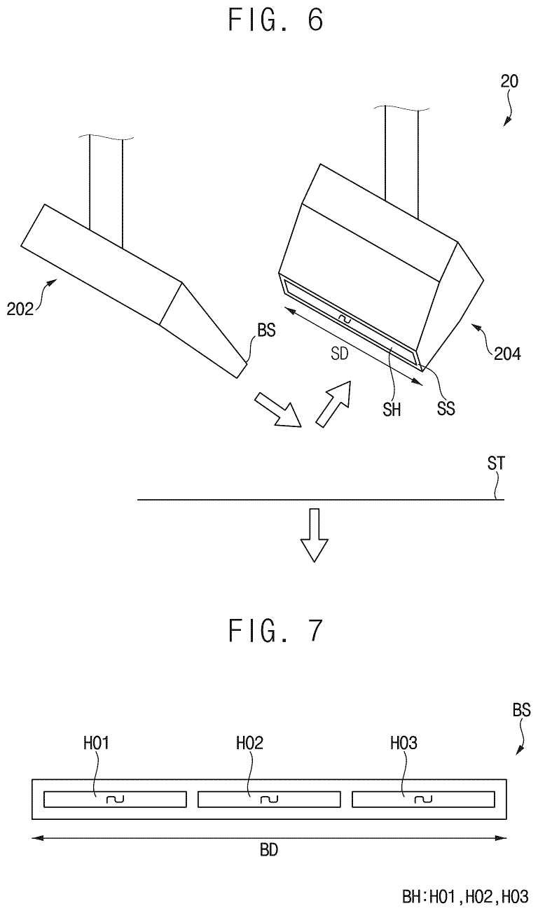

As described above, the second module 20 may be placed on the gantry GA. In an embodiment, the second module 20 may provide a gas to the mask (e.g., the mask MA of FIG. 2) disposed (e.g., mounted) on the stage ST to remove foreign substances from a surface of the mask MA. A detailed description of the second module 20 will be described later with reference to FIGS. 6, 7, 8, 9, and 10.

However, FIG. 1 illustrates one embodiment, and the mask quality management system 1 may further include various components. In an embodiment, the mask quality management system 1 may further include a controller, for example. The controller may control an operation of each of the stage ST, the gantry GA, the first module 10, and the second module 20. In an embodiment, a position of the gantry GA may be adjusted, or the first module 10 and/or the second module 20 may be turned on or off, for example. However, the disclosure is not limited thereto.

FIG. 2 is a view illustrating the first module included in the mask quality management system of FIG. 1.

Referring to FIG. 2, in an embodiment, the first module 10 may scan the entirety of the mask MA to determine the sagging degree of the mask sheet (e.g., the mask sheet MS of FIG. 3). Through this, whether the mask MA is defective may be checked.

In an embodiment, the first module 10 may include a beam generator 102, a path conversion member 104, a lens 106, a beam splitter 108, a detection sensor 110, and a camera 112.

In an embodiment, the beam generator 102 may emit light. In an embodiment, the beam generator 102 may be plural, for example. In this case, a plurality of lights may be emitted from the beam generator 102. Accordingly, a plurality of foci may be included (formed) on a focal plane of the mask MA, which will be described later, and the defect in the mask MA may be inspected at relatively high speed.

However, the disclosure is not limited thereto. In an embodiment, the beam generator 102 may be one, for example.

The path conversion member 104 may change a path of light emitted from the beam generator 102. In an embodiment, the path conversion member 104 may be a rotating mirror, for example. The light emitted from the beam generator 102 may be reflected by the path conversion member 104 and be incident on the mask MA. As the rotating mirror rotates, the position of the foci included (formed) on the mask MA may also be changed. The defect may be inspected for each position of the mask MA while changing the position of the foci.

However, the disclosure is not limited thereto. In an embodiment, the path conversion member 104 may be fixed, and the defect may be inspected for each position of the mask MA while moving the stage ST, for example.

In an embodiment, the lens 106 may cause light to enter the mask MA and include the focus. In an embodiment, the lens 106 may be an objective lens, for example. In an embodiment, light passing through the lens 106 may include the focus at the focal plane of the mask MA, for example.

In an embodiment, the lens 106 may include a first focus F1 at a first deformation position M1 of the mask sheet (e.g., the mask sheet MS of FIG. 3), and a second focus F2 may be included (formed) at a second deformed position M2, and a third focus F3 may be included (formed) at the mask frame (e.g., the mask frame MF in FIG. 3), for example.

Positions (e.g., Z-axis coordinates) of each of the first focus F1, the second focus F2, and the third focus F3 may be provided to the controller. In an embodiment, location information of each of the first focus F1, the second focus F2, and the third focus F3 may be provided to the controller through a wired communication method or a wireless communication method, for example.

The beam splitter 108 may split light. In an embodiment, the beam splitter 108 may transmit some of the light that has passed through the lens 106 and reflect others of the light. The some of the light reflected from the beam splitter 108 may be incident on the lens 106, and the others of the light transmitted through the beam splitter 108 may be incident on the camera 112.

In an embodiment, the detection sensor 110 may convert light reflected from the beam splitter 108 into an electrical signal. In an embodiment, the detection sensor 110 may convert a brightness of light passing through a plurality of openings defined in the mask MA into the electrical signal, for example.

In an embodiment, the detection sensor 110 may be a complementary metal oxide semiconductor (“CMOS”) sensor, a charge-coupled device (“CCD”) sensor, or the like, for example. However, the disclosure is not limited thereto.

In an embodiment, the camera 112 may generate image information based on light passing through the beam splitter 108. The image information may be provided to the controller. In an embodiment, the image information may be provided to the controller through the wired or the wireless communication, for example.

In an embodiment, the first module 10 may scan the entirety of the mask MA and calculate a distance between the first focus F1 and the second focus F2, and a distance between the second focus F2 and the third focus F3 (hereinafter also referred to as “vertical distance”) using the image information provided by the camera 112, location information of each of the first focus F1, the second focus F2, and the third focus F3.

In an embodiment, the first module 10 may measure the sagging degree of the mask sheet (e.g., the mask sheet MS of FIG. 3) from the mask frame (e.g., the mask frame MF of FIG. 3) at a level of micrometers (μm) or less. In other words, the vertical distance may be calculated with sub-micrometer precision. Accordingly, whether the defect in the mask may be quickly determined. A detailed description of a determining method of the defective mask will be described later with reference to FIGS. 3, 4, and 5.

In a case of the mask quality management system according to a comparative example, a microscope probe may be used. In this case, the microscope probe had to be manually focused and measured for each spot, so a measurement speed was slow, and a measurement accuracy was only about 1 micrometer (μm).

However, the first module 10 included in the mask quality management system 1 in embodiments of the disclosure may automatically focus and change the focus position quickly in real time to inspect the mask MA quickly. In an embodiment, the measurement speed of the first module 10 may be about 2 kilohertz (kHz) or more, and the measurement accuracy may be about 0.15 micrometer (μm) or less, for example.

For a mask quality management system according to another comparative example, a scanning electron microscope may be used. In this case, as part of the mask was destroyed and measured, the entirety of the mask could not be inspected, and the mask was damaged.

However, the first module 10 included in the mask quality management system 1 in embodiments of disclosure may automatically focus and change the focus position quickly in real time to inspect the entirety of the mask MA quickly. In addition, by non-contact inspecting method of the mask MA, the damage of the mask due to the destroy inspecting method may be prevented.

However, FIG. 2 illustrates one embodiment, and the first module 10 may further include various components. In addition, some components may be omitted from the first module 10 of FIG. 2. In an embodiment, the first module 10 may further include a focusing lens that focuses light, a filter that removes noise, or the like, for example.

FIGS. 3 and 4 are views illustrating a mask that is subject to inspection by the mask quality management system of FIG. 1.

Referring to FIGS. 3 and 4, in an embodiment, the mask MA may include the mask frame MF and the mask sheet MS. The mask sheet MS may be fixed to an upper surface of the mask frame MF. The mask sheet MS may be plural. In this case, the plurality of mask sheets MS may be spaced apart from each other.

In an embodiment, the mask MA may be used in a deposition process to deposit a deposition material on a substrate, for example.

In an embodiment, the substrate may include glass, quartz, plastic, or the like, for example. In an embodiment, the substrate may have flexible, bendable, or rollable characteristics, for example.

In an embodiment, the deposition material may include a material including a cathode electrode, a capping layer, an encapsulation layer, or the like, for example. In an embodiment, the deposition material may be a material that may be vaporized by heat, for example. In an embodiment, the deposition material may include an organic material, for example. In an embodiment, the organic material may include a light-emitting material, a hole injection material, a hole transfer material, an electron injection material, an electron transfer material, or the like, for example.

In an embodiment, the light-emitting material may include anthracene, phenyl-substituted cyclopentadiene, perylene, tris-aluminum (Alq₃), or the like, for example. These may be used alone or in any combinations with each other. However, the disclosure is not limited thereto. The light-emitting material may include various materials that may emit light of a predetermined color. In an embodiment, the predetermined color may be any one of red, blue, and green, for example.

In an embodiment, the hole injection material may include copper phthalocyanine (CuPc), poly(3,4,-ethylenedioxythiophene):poly(styrenesulfonate) (“PEDOT:PSS”), or the like, for example. These may be used alone or in any combinations with each other. However, the disclosure is not limited thereto. The hole injection material may include various materials that may facilitate hole injection from the anode electrode.

In an embodiment, the hole transfer material may include aromatic amine, or the like, for example. These may be used alone or in any combinations with each other. However, the disclosure is not limited thereto. The hole transfer material may easily transfer holes and may include various materials that may increase a probability of exciton formation by binding electrons to a light-emitting region.

In an embodiment, the electron transfer material may include a compound including or consisting of an electron puller or a metal compound capable of accepting electrons, for example. In an embodiment, the electron transfer material may include a compound including or consisting of a functional group that may attract electrons by resonance, such as cyanide group, oxadiazole, triazole, tris-aluminum, or the like, for example. These may be used alone or in any combinations with each other. However, the disclosure is not limited thereto. The electron transfer material may include various materials capable of stabilizing anion radicals generated when electrons are injected from the cathode electrode.

In an embodiment, the electron injection material may include a metal having electron affinity, for example. However, the disclosure is not limited thereto. The electron injection material may include various materials that may facilitate electron injection from the cathode electrode.

In an embodiment, the deposition process may be a chemical vapor deposition (“CVD”) process, for example. However, the disclosure is not limited thereto. In an embodiment, the mask MA may be a mask used in a photo process, for example.

As shown in FIG. 4, in a side view, the mask sheet MS may sag from the mask frame MF. In an embodiment, the sagging may be caused by various causes, such as incorrect welding or a decrease in tensile strength due to coating, for example.

The mask MA may be determined to be normal or defective by checking the vertical distance AD from one side of the mask frame MF to the mask sheet MS. In an embodiment, when the sagging degree of the mask sheet MS satisfies a predetermined numerical range, the mask may be determined to be a normal mask. However, when the sagging degree of the mask sheet is outside the predetermined numerical range, the mask may determine to be a defective mask. In an embodiment, as shown in FIG. 3, the mask MA may have a quadrangular shape, e.g., rectangular shape with a long side LD and a short side SD, for example. When an amount of deformation of the long side LD is more than about 300 micrometers or an amount of deformation of the short side SD is more than about 200 micrometers, the mask MA may be determined to be defective.

However, the disclosure is not limited thereto. In an embodiment, the shape of the mask MA, the amount of deformation, or the like may be changed in various ways, for example.

When the amount of deformation of the vertical distance AD from the one side of the mask frame MF to the mask sheet MS is outside the predetermined numerical range (e.g., the amount of deformation of the long side LD is about 300 micrometers or less, and/or the amount of deformation of the short side SD is outside of about 200 micrometers or less) the shape, size, and/or arrangement of the plurality of openings defined in the mask MA may differ from a design. When performing the deposition process using such the defective mask (i.e., the mask in which the vertical distance AD from the one side of the mask frame MF to the mask sheet MS is outside the predetermined numerical range), shadow areas (i.e. areas where the deposition material is not deposited) may occur in the display device.

A mask quality management system disclosure (e.g., the mask quality management system 1 of FIG. 1) in embodiments of the may check whether the vertical distance AD from the one side of the mask frame MF to the mask sheet MS satisfies the predetermined numerical range. Accordingly, the defective mask may be identified in advance before the deposition process is performed, and the defect occurred by the defective mask in the deposition process may be prevented.

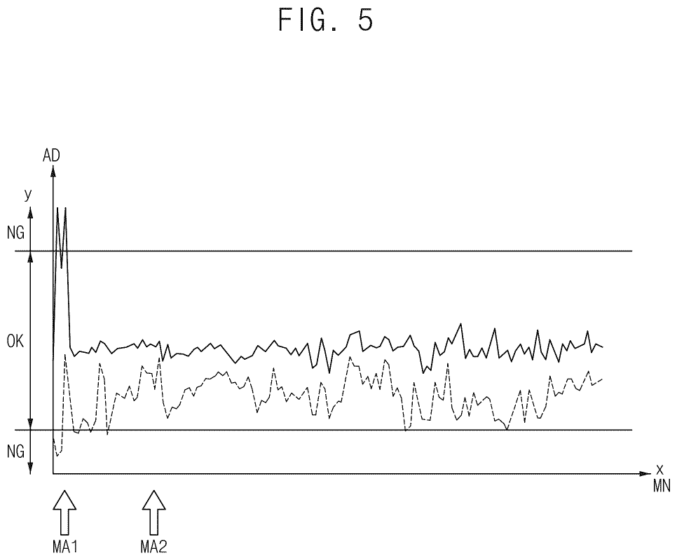

FIG. 5 is view illustrating an inspection result by the first module of FIG. 2.

In FIG. 5, a x-axis (horizontal axis) represents a mask number MN and a y-axis (vertical axis) represents the vertical distance AD from the one side of the mask frame to the mask sheet (e.g., the vertical distance AD from one surface of the mask frame MF to the mask sheet MS. Specifically, a solid line represents a maximum value of the vertical distance AD, and a dotted line represents the minimum value of the vertical distance AD.

Referring to FIG. 5, the first module (e.g., the first module 10 of FIG. 1) included in the mask quality management system (e.g., the mask quality management system 1 of FIG. 1) may identify the defective mask. As described above, in an embodiment, when the sagging degree of the mask sheet MS satisfies the predetermined numerical range, the mask may be determined to be the normal mask, and when the sagging degree of the mask sheet is outside the predetermined numerical range, the mask may be determined to be the defective mask.

In an embodiment, in the case of the first mask MA1, as a result of measuring the vertical distance AD from the one side of the mask frame MF to the mask sheet MS, an error numerical range NG outside the predetermined numerical range OK may be measured, for example. In this case, the first mask MA1 may be determined to be the defective mask and might not be used in the deposition process.

In an embodiment, in the case of the second mask MA2, as a result of measuring the vertical distance AD from the one side of the mask frame MF to the mask sheet MS, the predetermined numerical range OK may be measured, for example. In this case, the second mask MA2 may be determined to be the normal mask and may be used in the deposition process.

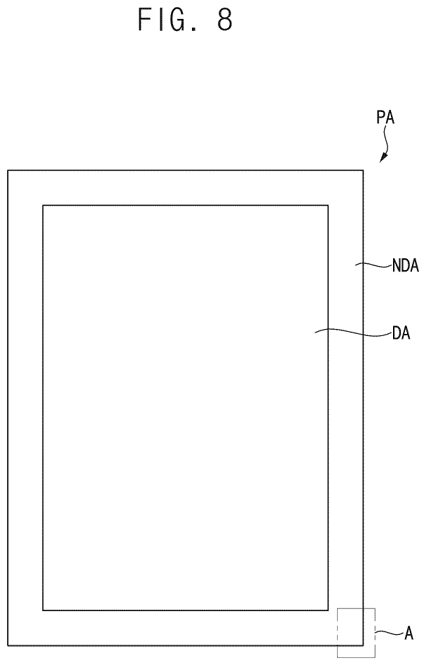

FIG. 6 is a view illustrating a second module included in the mask quality management system of FIG. 1. FIG. 7 is a view illustrating a vent of a blower included in the second module of FIG. 6.

Referring to FIGS. 6 and 7, a second module 20 may remove foreign substances from a surface of the mask (e.g., the mask MA of FIG. 2) disposed on the stage ST.

In an embodiment, the second module 20 may include a blower 202 and a suction 204.

In an embodiment, the blower 202 may provide gas to the mask. In an embodiment, the gas may be either nitrogen (N₂) or clean dry air (“CDA”). These may be used alone or in any combinations with each other. However, the disclosure is not limited thereto. In an embodiment, the gas may be used without limitation as long as the gas may remove the foreign substances from the surface of the mask, for example.

In an embodiment, a vent BH may be defined in a blowing surface BS of the blower 202. The gas discharged from the vent BH may drop the foreign substances from the surface of the mask.

In an embodiment, a plurality of vents BH may be defined in the blowing surface BS of the blower 202. In an embodiment, a first opening HO1, a second opening HO2, and a third opening HO3 spaced apart from each other in a direction BD may be defined in the blowing surface BS of the blower 202, for example. In an embodiment, the direction BD may be parallel to a direction along which a side (e.g., longer side) of the blowing surface BS extends, but the disclosure is not limited thereto.

When the vent BH is defined straight in the blowing surface BS of the blower 202, a flow rate of the gas may be different depending on a location of the vent BH. In an embodiment, a central portion of the vent BH may discharge more the gas than an edge portion of the vent BH, for example. In this case, sagging of the mask sheet (e.g., the mask sheet MS of FIG. 3) may be caused depending on the flow rate of the gas. When the flow rate is reduced to prevent sagging of the mask sheet, the foreign substance might not be removed from the surface of the mask.

In an embodiment, the suction 204 may suction the foreign substances that have fallen from the surface of the mask.

A suction hole SH may be defined in a suction surface SS of the suction 204. As the foreign substances is sucked in from the suction hole SH, the foreign substances flying to the upper part off the stage ST may be removed.

As shown in FIG. 7, when the plurality of vents BH are included (formed) on the blowing surface BS of the blower 202, the flow rate of the gas may be constant for each position of the vents BH.

In an embodiment, a down flow may be included (formed) in the stage ST. In an embodiment, the down flow may mean the flow of the gas from the second module 20 toward the stage ST, for example. The foreign substance not removed from the suction hole SH may be removed to a lower part of the stage ST along the down flow.

In the case of the mask quality management system according to the comparative example, a blower may be disposed on the upper part of the stage ST, and a suction may be disposed on the lower part of the stage ST. In this case, because the suction is disposed only at the lower part of the stage ST, the foreign substances flying to the upper part of the stage ST may be removed. As a result, the mask quality management system including the mask may be contaminated by the foreign substances.

In the case of the mask quality management system in embodiments of the disclosure, the blower 202 and the suction 204 may be disposed on the upper part of the stage ST, and the blower 202 and the suction 204 may be disposed on a same line, and a device for forming the down flow may be disposed on the stage ST. Accordingly, the foreign substances falling to the lower part of the stage ST may be removed to the lower part of the stage ST along the down flow, and the foreign substances flying to the upper part of the stage ST may be removed by the suction 204. As a result, the contamination of the mask quality management system including the mask by the foreign substances may be prevented.

However, FIG. 6 illustrates one embodiment, and the second module 20 may further include various components. In addition, some components may be omitted from the second module 20 of FIG. 6.

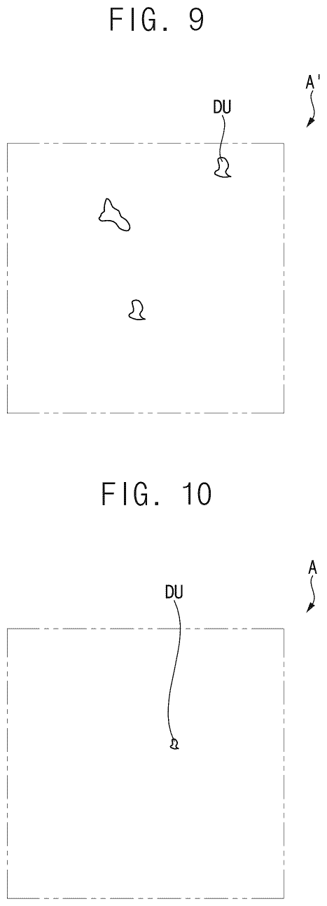

FIGS. 8, 9, and 10 are views illustrating a result of removing the foreign substances by the second module of FIG. 6.

FIG. 8 is a plan view illustrating a display device PA, FIG. 9 is an enlarged plan view illustrating a non-display area NDA before using the second module 20 of FIG. 6, and FIG. 10 is an enlarged plan view illustrating the non-display area NDA after using the second module 20 of FIG. 6, for example.

Referring to FIG. 8, the display device PA may include a display area DA and the non-display area NDA.

In an embodiment, the mask may include metal oxide, for example. In an embodiment, the mask may include aluminum oxide (AlOₓ), for example.

Fluorine radical (F*) may be generated during a mask cleaning process. As shown in a chemical formula below, the fluorine radical may react with the aluminum oxide to form a coarse particle (hereinafter also referred to as “foreign substances”).

AlOₓ+F*→AlF₂ <Chemical formula>

While performing the deposition process, the deposition material may also be deposited on the mask (e.g., the mask MA of FIG. 2). When the deposition material is not removed, the shape, the size, and/or the arrangement of the plurality of openings defined in the mask may differ from the design. In this case, as described above, the shadow area may occur in the display device PA.

To prevent the defect occurring in the display device PA, thee mask cleaning process may be performed after performing the deposition process. In an alternative embodiment, the mask cleaning process may be performed in real time while performing the deposition process.

The more the mask undergoes the mask cleaning process, the more foreign substances may be included (formed), and the more the foreign substances may fall on the display device PA during the deposition process. When the number and size of the foreign substances are large, the display device PA may be determined to be defective.

The mask quality management system (e.g., the mask quality management system 1 of FIG. 1) in embodiments of the disclosure may remove the foreign substances included (formed) on the surface of the mask frame MF. Accordingly, Foreign substances that may fall on the display device PA and cause the defect in the display device PA may be removed in advance, and yield of the display device PA may be enhanced.

In an embodiment, referring to FIG. 9, when the mask quality management system (e.g., the mask quality management system 1 of FIG. 1) in embodiments of the disclosure might not use, relatively large and numerous foreign substance DU may be seen in a portion A′ of the non-display area NDA, for example. The more foreign substances DU may be included (formed) when the mask undergoes the mask cleaning process, and the more the foreign substances DU may fall on the display device (e.g., the display device PA of FIG. 8) in the deposition process. When the number of the foreign substances DU are relatively numerous and large, the display device may be determined to be defective. As numbers of the defective display device increases, the yield of the display device may decrease.

However, referring to FIG. 10, for example, when using the mask quality management system (e.g., the mask quality management system 1 of FIG. 1) in embodiments of the disclosure, the size and number of the foreign substance DU may be reduced in a portion A of the non-display area NDA.

FIGS. 9 and 10 are briefly shown, but for example, before applying the mask quality management system, the number of foreign substances DU was detected about 79, while as a result of applying the mask quality management system, the number of foreign substances DU was about 1. It was detected and showed an effect of removing the foreign substances DU of more than 98.7%. That is, the foreign substances DU generated during the mask cleaning process may be removed by the mask quality management system. Accordingly, the yield of the display device may be enhanced.

What is claimed is:

1. A mask quality management system comprising:
a mask including:
a mask frame; and
a plurality of mask sheets fixed to an upper surface of the mask frame and spaced apart from each other;
a stage on which a mask of the plurality of mask sheets is seated; and
a first module disposed on the stage and measuring a sagging degree of the mask sheet from the mask frame by irradiating an intense light to the mask.

2. The mask quality management system of claim 1,
wherein the first module includes:
a beam generator that emits light;
a lens through which the light emitted from the beam generator passes and by which the light enters the mask and includes a focus;
a beam splitter through which the light passing through the lens is incident;
a detection sensor that converts the light reflected from the beam splitter into an electrical signal; and
a camera that generates image information based on the light passing through the beam splitter.

3. The mask quality management system of claim 1, wherein the first module measures the sagging degree of the mask sheet by scan throughout the mask.

4. The mask quality management system of claim 3, wherein,
in a case that the sagging degree of the mask sheet satisfies a predetermined numerical range, the mask is determined to be a normal mask, and
in a case that the sagging degree of the mask sheet is outside the predetermined numerical range, the mask is determined to be a defective mask.

5. The mask quality management system of claim 1, wherein the first module measures the sagging degree of the mask sheet from the mask frame at a micrometer level.

6. The mask quality management system of claim 1, further comprising:
a second module which is disposed on the stage, provides a gas to the mask.

7. The mask quality management system of claim 6,
wherein the second module includes:
a blower that provides the gas to the mask; and
a suction which suctions foreign substances dropped by the gas from the surface of the mask.

8. The mask quality management system of claim 7, wherein a down flow is formed in the stage.

9. The mask quality management system of claim 7,
wherein a plurality of vents through which the gas is discharged is defined in a blowing surface of the blower.

10. The mask quality management system of claim 6, wherein the gas includes either nitrogen gas or clean dry air.

11. A mask quality management system comprising:
a mask including:
a mask frame; and
a plurality of mask sheets fixed to an upper surface of the mask frame and spaced apart from each other;
a stage on which a mask of the plurality of mask sheets is seated; and
a second module which is disposed on the stage, provides a gas to the mask.

12. The mask quality management system of claim 11,
wherein the second module includes:
a blower that provides the gas to the mask; and
a suction which suctions foreign substances dropped by the gas from the surface of the mask.

13. The mask quality management system of claim 12, wherein a down flow is formed in the stage.

14. The mask quality management system of claim 12,
wherein a plurality of vents through which the gas is discharged is defined in a blowing surface of the blower.

15. The mask quality management system of claim 11, wherein the gas includes either nitrogen gas or clean dry air.

16. The mask quality management system of claim 11, further comprising:
a first module which is disposed on the stage and measures the sagging degree of the mask sheet in a direction crossing an extension direction of the mask by irradiate an intense light to the mask.

17. The mask quality management system of claim 16,
wherein the first module includes:
a beam generator that emits light;
a lens through which the light emitted from the beam generator passes and by which the light enters the mask and includes a focus;
a beam splitter through which the light passing through the lens is incident;
a detection sensor that converts the light reflected from the beam splitter into an electrical signal; and
a camera that generates image information based on the light passing through the beam splitter.

18. The mask quality management system of claim 16, wherein the first module measures the sagging degree of the mask sheet by scan throughout the mask.

19. The mask quality management system of claim 18, wherein,
in a case that the sagging degree of the mask sheet satisfies a predetermined numerical range, the mask is determined to be a normal mask, and
in a case that the sagging degree of the mask sheet is outside the predetermined numerical range, the mask is determined to be a defective mask.

20. The mask quality management system of claim 16, wherein the first module measures the sagging degree of the mask sheet from the mask frame at a micrometer level.
